(19) United States
(12) Patent Application Publication
(10) Pub. No.: US 2010/0003405 A1
(43) Pub. Date: Jan. 7, 2010

(54) METHOD FOR DEPOSITING LAYERS IN A CVD REACTOR AND GAS INLET ELEMENT FOR A CVD REACTOR

(76) Inventor: Johannes Käppeler, Wurselen (DE)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(21) Appl. No.: 12/094,254

(22) PCT Filed: Nov. 21, 2006
(86) PCT No.: PCT/EP2006/068712

§ 371 Date: Dec. 31, 2008

(30) Foreign Application Priority Data
Nov. 22, 2005 (DE) 102005055468.7

(51) Int. Cl. B05D 1/00; C23C 16/54

(52) U.S. Cl. 427/255.28; 118/715; 118/728

(57) ABSTRACT

The invention relates to a method for coating one or more substrates with a layer the components of which are passed into a process chamber (7) in the form or at least two gases by means of a gas inlet element. The gases are introduced into respective chambers (1, 2) of the gas inlet element that arranged one on top of the other and enter the process chamber (7) through gas outlet openings (3, 4) leading to the process chamber (7). The aim of the invention is to improve the aforementioned method or aforementioned device for producing homogeneous layers. For this purpose, each of the two chambers is subdivided into two compartments (1a, 1b; 2a, 2b) each which are arranged one on top of the other to be substantially congruent. The two process gases enter the process chamber separately from each other in the circumferential direction so that the substrates (10) lying on substrate supports (9), arranged in a ring and forming the base of the process chamber (7), are subsequently exposed to different process gases following a rotation of the substrate support (9) about its axis (9′).

The invention relates to a method for coating one or more substrates with a layer, the constituents of the layer being fed into a process chamber in the form of at least two gases by means of a gas inlet element, the gases being introduced in each case into chambers of the gas inlet element that are disposed one above the other and from there entering the process chamber through gas outlet openings, which open out into the process chamber.

The invention relates in addition to a gas inlet element for a CVD reactor, or a CVD reactor, the element having at least two chambers disposed one above the other, gas outlet openings starting in each case from the lower wall of the chambers, the openings opening out into the process chamber for supply, into the process chamber, of in each case a process gas brought into the chambers by means of a feed line, the bottom of the process chamber being formed by a substrate holder that can be driven in rotation.

A CVD reactor is known from U.S. Pat. No. 5,871,586, which has a gas inlet element of the showerhead kind, by which a plurality of process gases may be fed into a process chamber. The underside of the gas inlet element has a plurality of gas outlet openings that are distributed uniformly over the substantially circular face, and the outlet openings open out in the direction of a substrate holder located underneath the gas inlet element. A plurality of substrates to be coated lie on this substrate holder, which is driven in rotation, and are distributed in an annular arrangement about the center of rotation. The substrate holder may be heated from below by means of a suitable heater. The gas inlet element has a plurality of chambers disposed one above the other. A lower chamber forms a chamber for cooling medium, through which a cooling medium flows, in order to cool the underside of the gas inlet element to a temperature that is lower than the reaction temperature of the process gases exiting from the gas inlet element. Above this chamber for cooling medium, there are two chambers that are separated from each other in a gas-tight manner and extend for the most part above the cross-sectional plane of the gas inlet element, the plane as a whole being rotationally symmetrical. Each of the two chambers is supplied with a different process gas. One of the two process gases may be a hydride, for example NH₃, arsine or phosphine. Another process gas is a metal-organic compound, so that layers of the elements of the fifth and third or the second and sixth main group may be deposited on the substrates. Each of the two chambers is connected to the underside of the process chamber by gas outlet passages. Other starting materials may also be used, in particular metal-organic starting materials.

A so-called ALD method is described in the state of the art. In this method, the two process gases are not fed into the process chamber at the same time, but alternatingly. Optionally, a purge gas may be fed into the process chamber between introduction of the one and the other process gas. It is an object of this method to alternatingly deposit on the substrate substantially a monolayer of one of the constituents, for example of the III constituent or the II constituent, and then a monolayer of the V constituent or the VI constituent. By this method, an absolute homogeneity of the layer thickness is said to be achieved.

A CVD reactor for depositing III-V layers on substrates is knows from DE 100 43 601 A1. In this, a gas inlet element projects into a process chamber that lies in a horizontal plane. A cooled member of the gas inlet element projects into the center of the process chamber, the bottom of which forms the substrate holder. A hydride, for example arsine or phosphine, flows out of the underside of the gas inlet element into the process chamber. The hydride is there diverted into the horizontal direction, in order to flow in the radial direction to the substrates. Above this outlet opening, there is provided a further gas outlet opening extending over the entire periphery of the gas inlet element, through which a metal-organic compound, for example, TMG, enters the process chamber.

US 2005/0158469 describes a showerhead reactor, in which the chambers of the gas inlet element are formed by passages arranged in a comb-like manner.

JP 03170675 A describes a gas inlet element having two chambers disposed one above the other, in which each is connected to the wall facing the process chamber by a plurality of outlet openings. The individual outlet openings may be individually closed.

In the case of the gas inlet element, which is described by U.S. Pat. No. 5,950,925, gas distribution passages that extend in the radial direction are provided, in order to ensure a spatially uniform distribution of the gas.

A gas inlet element is known form U.S. Pat. No. 6,800,139, in which a plurality of chambers is disposed in one plane at different radial spacings from the center, so that a different composition of gas may be introduced into the process chamber through a central region of the gas outlet face than is introduced through a peripheral region of the gas outlet face.

A CVD reactor is known from U.S. Pat. No. 4,976,996 in which the process gas is fed into the process chamber from a peripheral wall of the process chamber. The process gas flows through the process chamber in the horizontal direction from radially outward toward the center. Different gases may be introduced in different sectors of the process chamber. Since the substrate holder can be rotated, the substrates disposed on the substrate holder may be exposed to different gas phases in succession. The exposure times may be controlled by the speed of rotation.

It is an object of the invention to develop the method referred to at the beginning and the apparatus referred to at the beginning for the production of homogeneous layers.

This object is met by the invention specified in the claims, each of the claims representing in principle an independent solution to the problem.

The method claim provides first and foremost that as a result of a particular configuration of the gas inlet element and an appropriate division of the chambers into a plurality of compartments, circumferentially displaced in-feed of different process gases into the process chamber is possible. It is provided that different process gases flow, separately from one another, into different circumferential portions of the process chamber. The substrates that rotate on a circular path underneath the gas inlet element are therefore exposed alternatingly to the different process gases, so that a kind of ALD method is possible, without having to carry out a cyclical change of gas in the process chamber. It is especially advantageous if, between the circumferential zones that are supplied with the process gases, purge zones are provided, in which an inert gas or another purge gas may, be fed into the process chamber. It also proves to be advantageous for likewise a purge gas or inert gas to be fed into the process chamber through the center of the gas inlet element. The gas flow of the purge gases is set so that it just suffices to avoid any intermingling of the individual process gases. Nevertheless, the apparatus is however able to implement the generic method, if all of the compartments of either chamber are supplied with the same process gas. Both process gases then exit from the underside of the gas inlet element at every point. There are then no zones in which different process gases are fed into the process chamber. Gas phase reactions may then in fact occur between the reactants.

The claim relating to the gas inlet element provides first and foremost that each of the two chambers is divided into at least two compartments and the compartments of the chambers are located one above the other to be substantially congruent. Here also it may be provided that purge gas outlet openings are provided on the underside of the gas inlet element, in the region of the partition zone between the compartments. In order to introduce the purge gas into the compartments, is sufficient for a plurality of openings to connect, in the manner of comb, with a purge gas supply line in the radial direction. These separate openings are then used as required to supply the process chamber with purge gas, so that neighboring zones, in which in each case different process gases flow into the process chamber, are separated by a gas curtain. It is however also provided that one compartment of one of the two chambers or two compartments, disposed one over the other, of the two chambers, are used for admission of purge gas into the process chamber. In a first configuration of the invention, it is provided that each chamber is divided into two compartments. The partition wall of each chamber that separates the compartments then lies preferably on a transverse line through the gas inlet element, which is in the shape of a circular disk. The partition walls are located one above the other. It is however also possible for the partition walls, which lie one above the other in alignment, to be arranged in each case in the shape of a cross or in the manner of a star. The compartments may extend over different circumferential angles. Smaller and large compartments may be provided. Preferably the compartments enclosing a greater circumferential angle serve for feeding process gases into the process chamber. The smaller compartments, which extend only over a lesser circumferential angle about the center of the process chamber or about a central compartment, serve for feeding purge gas into the process chamber. The speed of rotation of the substrate holder is matched to the process in such a way that when the substrate passes through the circumferential zone of a compartment through which a process gas is fed into the process chamber, just a monolayer of a constituent is deposited on the surface of the substrate. The method is especially suitable for use of those process gases that innately condense only as a single layer on the substrate surface and thus grow in a self-limiting manner. Rotation of the substrate has the result that different constituents are deposited alternatingly on the substrate. If the individual compartments, through which the process gases enter the process chamber in turn, are separated by purge zones, the reactants also have enough time to react with one another to form layers and crystals.

The concept described above on a gas inlet element configured in the manner of a showerhead, may also be realised for a gas inlet element as is described by, DE 100 43 601 A1 OR DE 101 53 463 A1. There also, chambers are provided that are disposed one above the other. These are located however between the top and the bottom of the process chamber. The two chambers of the gas inlet element are supplied with process gas by means of gas supply lines extending in the vertical direction. These process gases then enter the respective associated compartments of the individual chambers, in order then to exit in the horizontal direction from the gas inlet element but in different circumferential directions. Semi-circular outlet openings are provided, which are disposed one above the other. Depending on the number of compartments, outlet openings may however also be provided that have the shape of a quarter of a circle or a third of a circle. Furthermore, it is possible for the outlet openings for the process gases that are different from one another to also be separated by a zone from which a purge gas exits. The process gases exiting from the outlet openings flow in the radial direction through the process chamber and over the substrates grouped around the gas inlet element. Crystal-forming reaction products are formed by gas phase reactions or by surface reactions.

The gas mixing device by which the individual compartments of the chambers are supplied with the process gas assigned to each chamber, have first gas metering devices for a first process gas and second gas metering devices for a second process gas. The first process gas may be one of the above-mentioned metal hydrides. The second process gas may be a metal-organic compound. The gas mixing device has a changeover valve arrangement. By means of this changeover valve arrangement, all compartments of each chamber may be supplied with the process gas respectively assigned to that chamber. For example, it is possible for all compartments of the upper chamber to be supplied with a hydride and all compartments of the lower chamber to be supplied with a metal-organic compound. The hydride and the metal-organic compound are as a rule fed into the respective chamber with a carrier gas, for example hydrogen or nitrogen or a noble gas. As a result of the changeover valve arrangement, it is however also possible for in each case only a selection of compartments of either chamber to be supplied with the process gas assigned to that chamber. These compartments supplied with the respective process gas do not lie one above the other, but are located circumferentially displaced with respect to one another. The other compartments that are not supplied With the process gas are supplied with a purge gas. The purge gas then enters the process chamber from the underside of the gas inlet element together with the respective constituents. Zones are thus formed that alternate with one another in the circumferential direction, and in which different process gases and optionally only purge gases are fed into the process chamber.

Exemplary embodiments of the invention are explained below on the basis of accompanying drawings, in which:

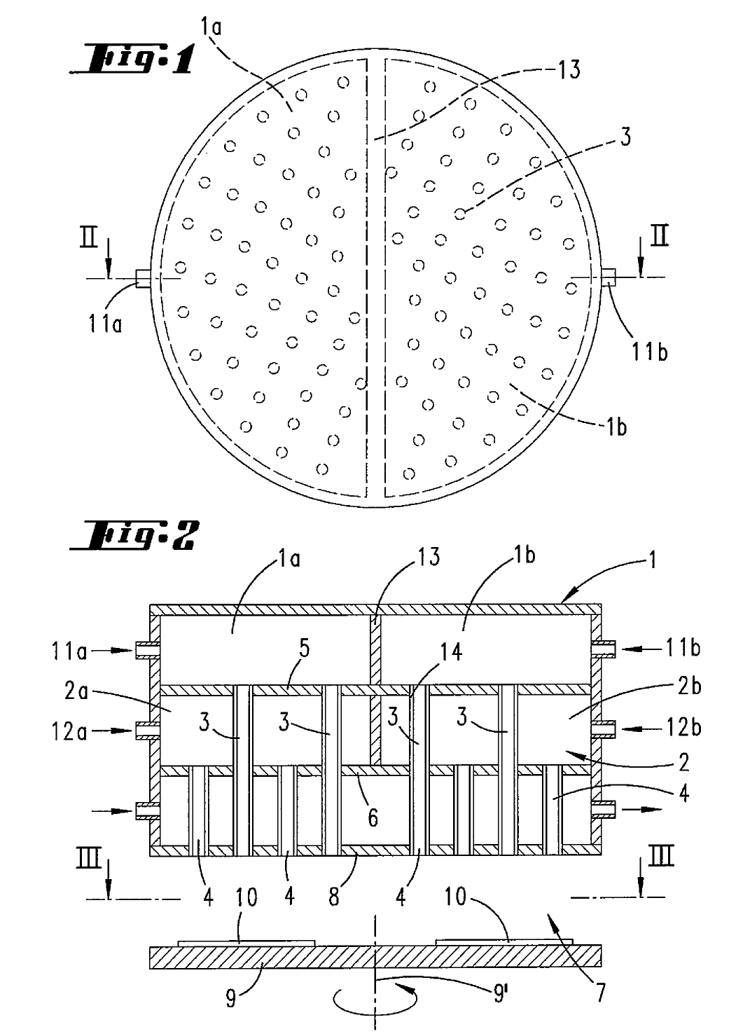

FIG. 1 shows a plan view, not shown to scale, of a gas inlet element having compartments designated 1a, 1b of a chamber 1, the compartments being connected to the underside of the gas inlet element by passages 3.

FIG. 2 shows a section, not to scale, on line II-II in FIG. 1,

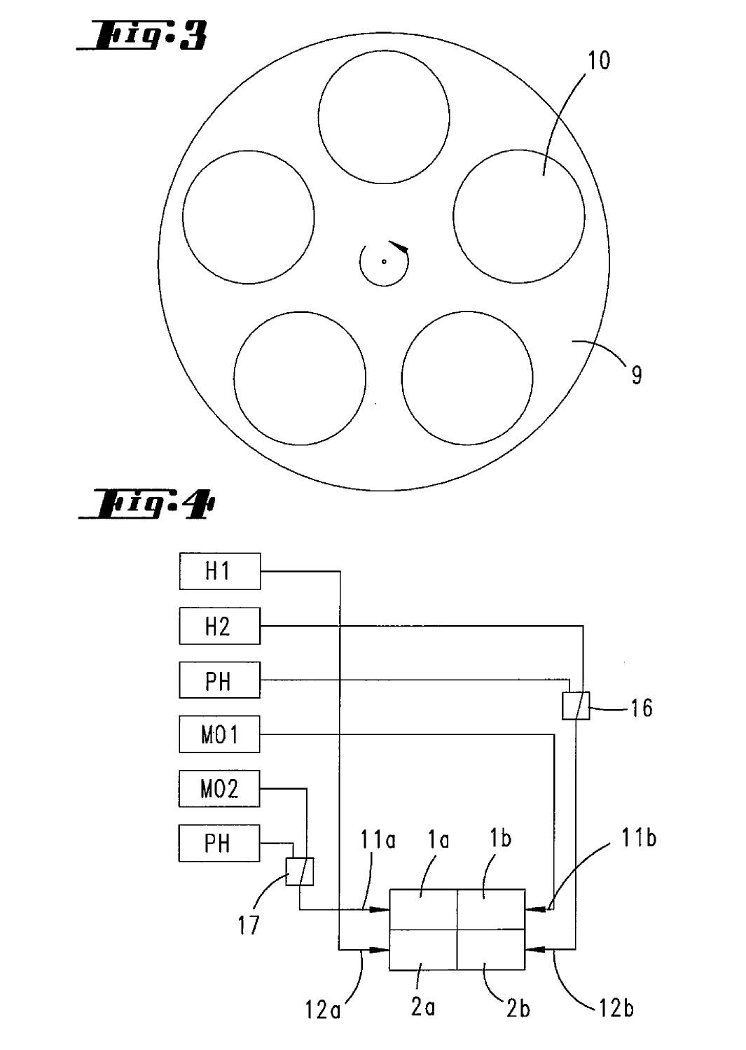

FIG. 3 shows a section on line III-III in FIG. 2,

FIG. 4 shows a simple example of a gas mixing arrangement for supply of the compartments 1a, 1b, 2a, 2b of the chambers 1, 2 of the gas inlet element illustrated diagrammatically in FIGS. 1 and 2,

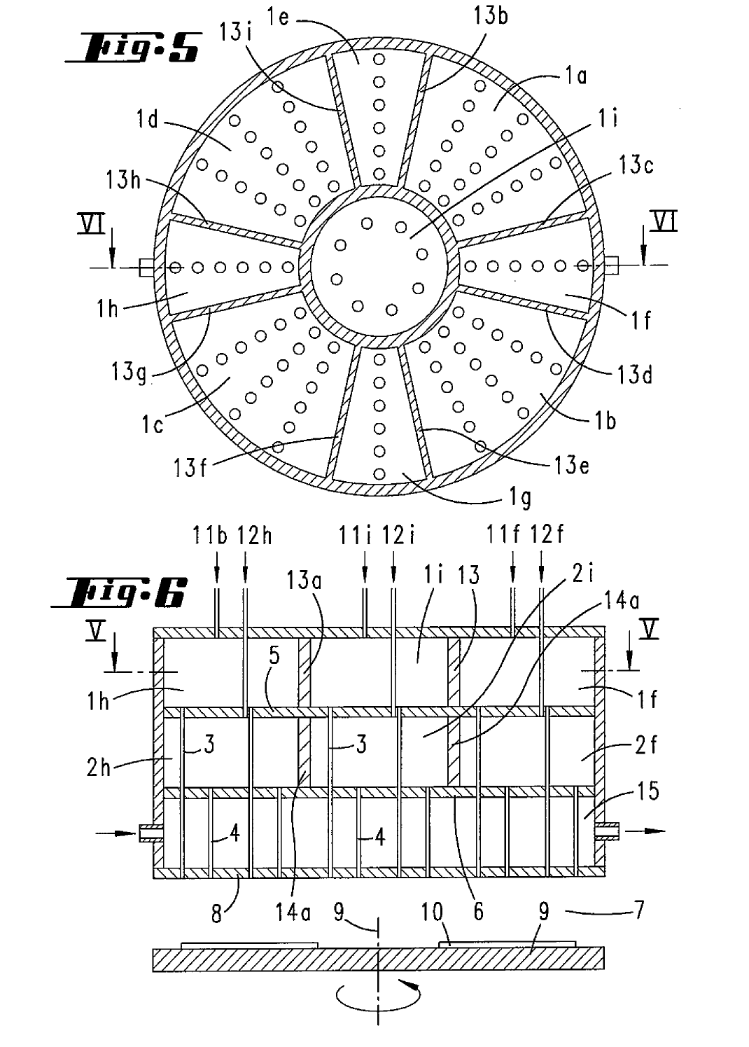

FIG. 5 shows a cross-section, not to scale, through the upper chamber 1 of a gas inlet element of a second exemplary embodiment,

FIG. 6 shows the section on line VI-VI in FIG. 5,

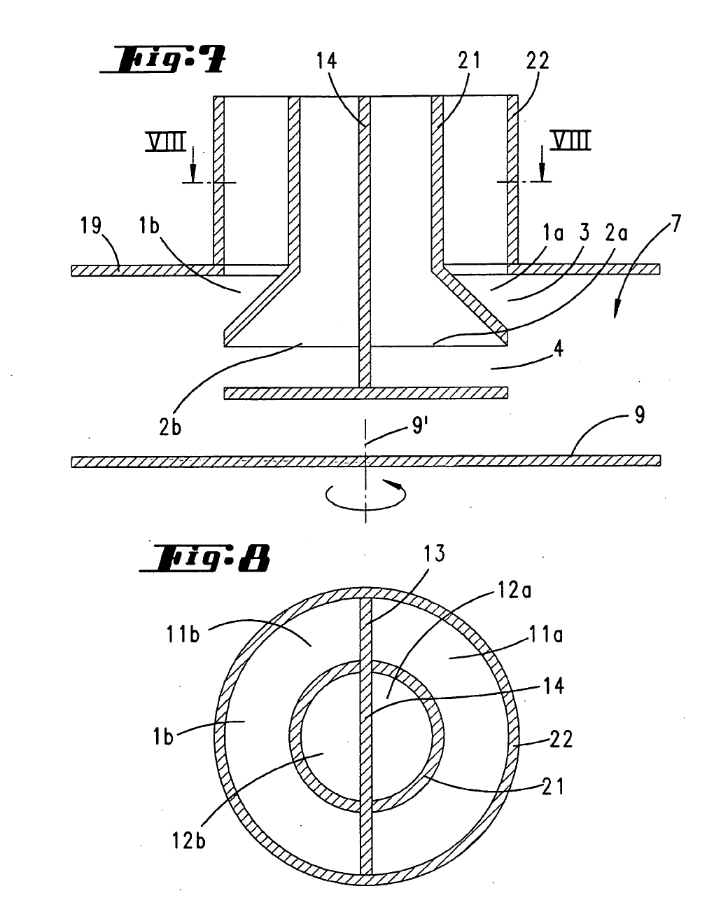

FIG. 7 shows a cross-section through a process chamber of a further exemplary embodiment of the invention.

FIG. 8 shows a section on line VIII-VIII in FIG. 7,

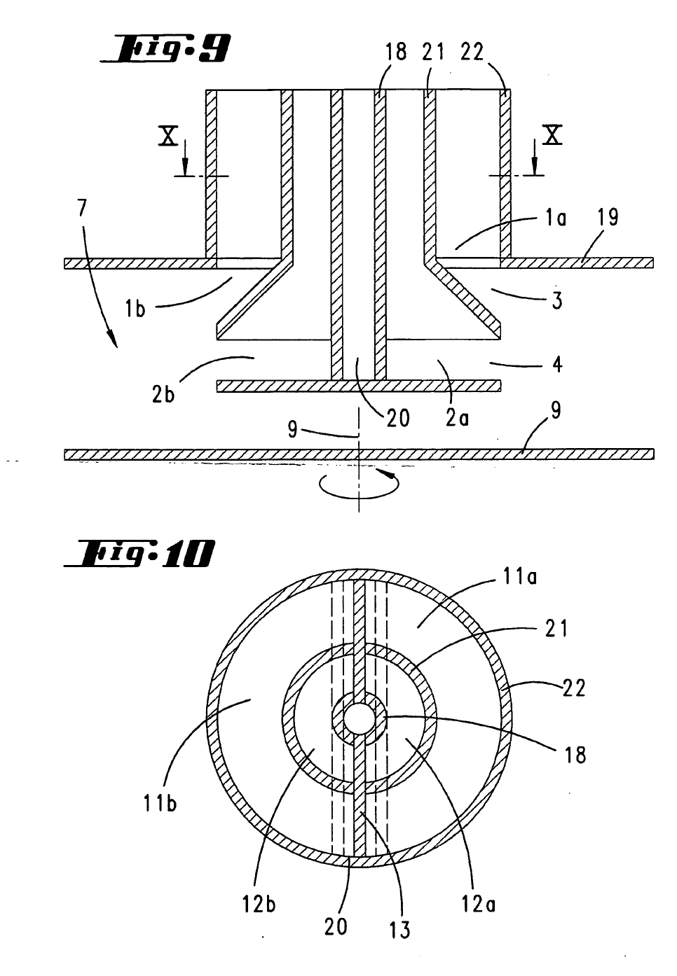

FIG. 9 shows an illustration corresponding to FIG. 7 for a further exemplary embodiment,

FIG. 10 shows a section on line X-X in FIG. 9:

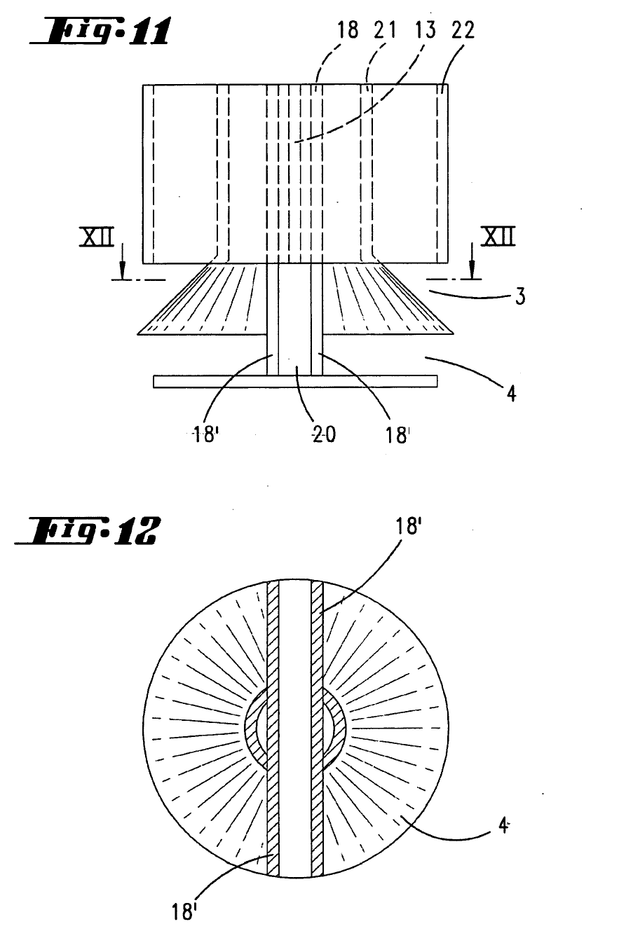

FIG. 11 shows a side view of a gas inlet element in accordance with the exemplary embodiment illustrated in FIGS. 9 and 10, and

FIG. 12 shows a section on line XII-XII in FIG. 11.

A CVD reactor, in which the gas inlet elements are disposed, has a gas mixing system. Some components of a gas mixing system of this kind are shown in FIG. 4. These are the components required in order to explain the invention. H₁ and H₂ are gas metering devices for hydrides, for example NH₃, ASH₃ or PH₃. These metering devices H₁ and H₂ consist of mass-flow controllers and valves. A compartment 2b of a chamber 2 of a gas inlet element is supplied with a hydride by the gas metering device H₁. The hydride delivered by the gas metering device H₂ may be fed into the second compartment 2a of the chamber 2 when the changeover valve 16 is in an appropriate position, so that the entire chamber 2 is supplied with a hydride. A gas metering device designated MO₁ supplies a compartment 1b of a chamber 1 with a metal-organic constituent. A gas metering device designated MO₂ supplies the second compartment 1a of the chamber 1 with a metal-organic constituent when the changeover valve 17 is in an appropriate position. During operation of this kind, both process gases exit from the underside of the gas inlet element substantially at every point. The vent lines, which are generally necessary, are not illustrated for the sake of better clarity.

If the changeover valves 16, 17 are changed over, the hydride flows into the compartment 2a of the lower chamber just as before, but the purge gas provided by the gas metering device PH flows into the compartment 2b located alongside. When the changeover valve 17 is in an appropriate position, the purge gas provided by the gas metering device PMO flows into the compartment 1a disposed above the compartment 2a, while the metal-organic constituent flows into the compartment 1b which is located diagonally opposite the compartment 2a. As a result, a metal-organic constituent flows into the zone, underneath the gas inlet element, that is associated with the compartments designated “b”, and the hydride flows into the circumferential zone that is associated with the “a” compartments.

A gas mixing system for more than two compartments in each chamber looks correspondingly bulkier. It has an appropriately greater number of changeover valves 16, 17 and correspondingly more gas metering devices.

The gas inlet system illustrated in FIGS. 1 and 2 consists substantially of a stainless steel housing having a top plate, two intermediate plates 5, 6 and a bottom plate 8. Two chambers 1, 2 are formed, located one above the other, chamber 1 forming two compartments 1a and 1b. Each of the compartments 1a, 1b has a shape which is substantially half-cylindrical in cross-section and they are separated from one another in a gas-tight manner by a partition wall 13. A supply line 11a opens into the compartment 1a and a supply line 11b opens into the compartment 1b.

The bottom plate 5 of the chamber 1 is connected to the bottom plate 8 by means of a plurality of small tubes, plate 8 forming the underside of the gas inlet element. These small tubes form gas exit passages 3, through which the process gas introduced into the chamber 1 or purge gas may flow into the process chamber 7 disposed underneath the gas inlet element.

The second chamber 2 is underneath the lower wall 5 of the upper chamber 1. The second chamber 2 is also connected to the bottom plate of the gas inlet element by means of small tubes, which start at the lower wall 6, so that gas exit passages 4 are formed, through which the process gas or purge gas, which is introduced into the chamber 2, may flow into the process chamber 7.

The process chamber 2 is divided into two compartments 2a, 2b by means of a transversely extending partition wall 14. An individual gas supply line 12a, 12b is assigned to each compartment 2a, 2b, through which either a process gas or a purge gas may be fed into the chamber 2a, 2b.

Underneath the two chambers 1, 2, there is a third chamber 15, which is not subdivided. All of the small tubes forming gas exit passages 3, 4 extend through this chamber 15. A cooling medium flows through the chamber 15, this cooling the bottom plate 8 of the gas inlet element and the small tubes.

Underneath the underside of the gas inlet element 8, there is a substrate holder 9, made for example from graphite. The substrate holder 9 is located substantially congruently underneath the gas inlet element and has likewise the shape of a circular disk. The substrate holder 9 can be rotated about its axis 9′ by means of a drive element, not illustrated. The substrates 10, which are in an annular arrangement on the substrate holder 9, are then rotated under the gas exit face of the gas inlet element.

If, for example, the compartment 2a is supplied with a hydride, the compartment 2b located alongside is supplied with a purge gas, the compartment 1b disposed diagonally above the compartment 2a is supplied with a metal-organic compound and the compartment 1a located alongside is again fed with a purge gas, different process gases thus enter the process chamber 7 from the gas exit face of the gas inlet element in different zones. The hydride enters the process chamber in a circumferential zone underneath the compartment 2a and extending approximately over 180°. The metal-organic constituent enters the process chamber in the circumferential zone located alongside, which likewise extends approximately over 180°. A purge gas may be introduced between the two zones by way of a purge inlet passage, not illustrated. If the substrate holder 9 is rotated during this manner of operation of the reactor, the substrates 10 lying on the holder are exposed to one or the other process gas, during alternating time periods.

In the exemplary embodiment of a gas inlet element illustrated in FIGS. 5 and 6, each chamber 1, 2 has altogether 9 compartments 1a-1i and 2a-2i.

In this exemplary embodiment also, the partition walls 13a-13i and 14a-14i separating the individual compartments 1a-1i, 2a-2i are located in alignment, one above the other.

Each of the two chambers 1, 2, which are located one above the other, has a central compartment 1i, 2i. The central compartment 1i, 2i is surrounded by an annular wall 13a. This central compartment 1i, 2i may be fed either with a process gas assigned to the chamber 1, 2 or with a purge gas, so that a central space that is purged and free of process gas is established in the process chamber 7.

The central compartment 1i, 2i is surrounded by a plurality of partition walls 13b-13i and 23b-23i respectively, which extend radially. These partition walls 13b-13i, 23b-23i extend across the chambers. Compartments 1a-1h and 2a-2h respectively are formed by the partition walls and are disposed one after the other in the circumferential direction. Compartments 1a, 1b, 1c, 1d, which extend over a greater circumferential angle, are thus formed. Chamber 2 forms chambers 2a-2d which are located correspondingly and congruently with the compartments of chamber 1. The process gases may be fed into the process chamber 7 through these compartments 1a-1d and 2a-2d that are arranged in the shape of a cross. This is again also effected in an alternating manner, so that for example the oppositely located compartments 1a and 1c are fed with a metal-organic compound. The compartments 1b and 1d are by contrast supplied with a purge gas, these compartments being located displaced by 90° with respect to compartments 1a and 1c. In chamber 2, compartments 2a and 2c are fed with a purge gas. The compartments 2b and 2d of the lower chambers, located under the purged compartments 1b and 1d, are fed with hydride.

Purge gas compartments 1e-1h and 2e-2h are disposed between those compartments 1a-1d and 2a-2d that extend over a great circumferential angle. These compartments 1e-1h and 2e-2h may be fed selectively with the process gas associated with the respective chamber 1, 2 or with a purge gas.

In the case of the gas inlet element illustrated in FIGS. 5 and 6, all process gases may be fed into the process chamber 7 in a mixture by appropriate feed of the compartments. In the case of a switching position of the gas mixing system different from that above, only a selection of the compartments are fed with the process gas, the non-selected compartments being fed with a purge gas, so that circumferential regions are established in the process chamber 7, in which the substrate is exposed to a hydride or to a metal-organic compound.

The further exemplary embodiment illustrated in FIGS. 7 and 8 is for a so-called planetary reactor, in which the gas inlet element is in the centre of a process chamber 7. The process chamber has a process chamber top 19, this having a central opening, through which the gas inlet element projects inwardly into the process chamber, the inlet element being in particular water-cooled. The bottom 9 of the process chamber is underneath the gas inlet element and the process chamber top 19, the base being formed by a substrate holder, which is driven in rotation about its central axis 9′. A plurality of substrates is located on the region of the substrate holder 9 that surrounds the gas inlet element. The substrates may in turn lie on individual susceptors, which are driven in rotation by suitable means. The gas flowing out of the gas inlet element flows through the process chamber 7 in the radial direction.

The drawings show the gas inlet element only schematically. It is pertinent that different process gases, in particular a hydride or a metal-organic compound, flow through the gas inlet element in a vertical direction through gas lines. For this, the gas inlet element has an outer tube 17, in which there is located a tube 16 which is of smaller diameter. The lumen formed thereby is divided into feed lines 11a, 11b and 12a, 12b, in each case by transversely extending partition walls 13, 14. A metal-organic compound flows into a first chamber 1a, 1b through the outer feed lines 11a, 11b. The chamber forms two compartments 1a, 1b, which lie in a common horizontal plane and extend over a half-circle. The compartments form the end zones of the feed lines 11a, 11b.

The inner tube 17 likewise forms compartments 2a, 2b, which lie in a common horizontal plane and extend over a half-circle, these compartments being substantially the end portions of the feed lines 12a, 12b.

As is to be gathered from the cross-sectional drawing in FIG. 7, the compartment 1a is located vertically above the compartment 2a The compartment 1b is located vertically above the compartment 2b. The central tube 17 widens out in the shape of a cone toward the end of the tube that projects into the process chamber 7 and thus forms a partition wall between the compartments 1a, 2a and 1b, 2b respectively.

The compartments 1a, 1b have outlet openings 3 which extend over a 180° circumferential surface. These outlet openings 3, which face away from each other, serve for discharge into process chamber 7 of a metal-organic process gas transported by a carrier gas. The hydrides enter the process chamber through the outlet openings 4 of the compartments 2a, 2b, these openings being located below the openings 3 and likewise extending over a 180° circumferential surface.

Operation of this exemplary embodiment corresponds to the operation of the exemplary embodiments discussed previously. It is possible to feed like process gases in each case into the compartments 1a, 1b and 2a, 2b respectively. As an alternative to this, a process gas may be fed only into the compartments 1a and 2b. Only an inert gas is then fed into the compartments 1b and 2a.

When the substrate holder 9 rotates about its axis 9′, the substrates lying on it enter alternatingly into a gas phase, which contains one or the other process gas.

The exemplary embodiment illustrated in FIGS. 9 to 12 is a variant of the exemplary embodiment illustrated in FIGS. 7 and 8. Here also, the process gas exits in the horizontal direction from the compartments 1a, 1b, 2a, 2b. Differing from the exemplary, embodiment described previously, here however the outlet openings 3, 4 from the individual compartments 1a, 1b and 2a, 2b are separated by a purge gas opening 20. The purge gas is fed in by means of a central tube 18. The purge gas tube 18 is in the center of the partition wall 14. The purge gas tube 18 widens out in the end region of the gas inlet element, to that the purge gas may flow into the process chamber out of diametrically opposite outlet openings 20.

In an exemplary embodiment which is not illustrated, a central process gas feed may in addition be provided, this opening out in the end face of the gas inlet element, as is the case for the state of the art noted at the beginning. The hydride may for example be conducted into the process chamber through this central gas feed line, as is the case in the state of the art. Different metal-organic compounds may, then be fed into the process chamber through the compartments that extend over different circumferential angles; accordingly, metal-organic compounds containing for example indium or gallium may be fed into different segments of the process chamber. The hydride is then fed into the process chamber, but in every direction, thus over 360°.

All features disclosed are (in themselves) pertinent to the invention. The disclosure content of the associated/accompanying priority documents (copy of the prior application) is also hereby incorporated in full into the disclosure of the application, including for the purpose of incorporating features of these documents in claims of the present application.

1. A method for coating one or more substrates with a layer, the constituents of the layer being fed into a process chamber (7) in the form of at least two gases by means of a gas inlet element, the gases being introduced in each case into chambers (1, 2) of the gas inlet element that are disposed one above the other and from there entering the process chamber (7) through gas outlet openings (3, 4), which open out into the process chamber (7), characterized in that as a result of dividing each of the two chambers into in each case at least two compartments (1a, 1b; 2a, 2b), the compartments being located one above the other and to be substantially congruent, the two process gases enter the process chamber separated from one another in a circumferential direction, so that substrates (10), which lie in an annular arrangement on a substrate holder (9) that forms a bottom of the process chamber (7), are exposed to the two process gases one after the other as a result of rotation of the substrate holder (9) about its axis (9′).

2. A method according to claim 1, further characterized in that in each case only compartments (1a, 2b) that are not disposed one above the other are fed with a process gas and other compartments (1b, 2a) are fed with a purge gas.

3. A method according to claim 2, further characterized in that some of the compartments (1e, 1f, 1g, 1h) are disposed in the circumferential direction between others of the compartments (1a, 2b, 1c, 2d) that are fed with process gases, the former compartments (1c, 1f, 1g, 1h) being fed with a the purge gas, for exit of the purge gas from an underside of the gas inlet element.

4. A gas inlet element for a chemical vapor deposition (CVD) reactor, the element having at least two chambers (1, 2) disposed one above the other, gas outlet openings (3, 4) starting in each case from a lower wall (5, 6) of the chambers, the gas outlet openings opening out into a process chamber (7) for supply, into the process chamber (7), of in each case a process gas brought into the chambers (1, 2) by means of a feed line (11, 12), a bottom of the process chamber being formed by a substrate holder (9) that can be driven in rotation, characterized in that each of the at least two chambers (1, 2) is divided in each case into at least two compartments (1a, 1b; 2a, 2b), and the compartments (1a, 1b; 2a, 2b) of the various at least two chambers (1, 2) are located one above the other to be substantially congruent and in each case have associated supply lines (11a, 11b; 12a, 12b).

5. A gas inlet element according to claim 4, further characterized by purge gas outlet openings disposed between the at least two compartments (1a, 1b; 2a, 2b) in a region of a partition zone.

6. A gas inlet element according to claim 4, further characterized in that substrates (10) are disposed in an annular manner about a center (9′) of the substrate holder (9), which is rotationally symmetric.

7. A gas inlet element according to claim 4, further characterized by a star-shaped or cross-shaped division of the at least two chambers (1, 2) into a plurality of compartments (1a-1i; 2a-2i).

8. A gas inlet element according to claim 4, further characterized by a central compartment (1i, 2i) for selective introduction of a process gas or a purge gas.

9. A gas inlet element according to claim 4, further characterized by a plurality of compartments arranged in a distributed manner in a circumferential direction for supply to the process chamber (7) either of a purge gas or a process gas.

10. A gas inlet element according to claim 9, further characterized in that partition walls (13, 14), which separate the compartments from one another in a gas-tight manner, are arranged aligned one above the other.

11. A gas inlet element according to claim 4, further characterized by a chamber (15) for a cooling medium, which is disposed underneath the chambers (1, 2), and a bottom (8) of which forms an underside of the gas inlet element.

12. A gas inlet element according to claim 11, further characterized in that the gas outlet openings (3, 4) are passages, which open out into the underside (8) of the gas inlet element, this underside forming a top of the process chamber (7).

13. A gas inlet element according to claim 12, characterized in that the gas outlet openings (3, 4) are circumferential openings of the gas inlet element that are disposed one over the other, the gas inlet element projecting into the process chamber (7).

14. A gas inlet element according to claim 4, characterized in that outlet openings (20) of a purge gas line (18) are disposed between the gas outlet openings (3, 4) of the compartments (1a, 1b, 2a, 2b).

15. A gas inlet element according to claim 7, characterized by a gas mixing device comprising first gas metering devices (H₁, H₂) for a first process gas and second gas metering devices (MO₁, MO₂) for a second process gas, and a changeover valve arrangement (16, 17), by means of which all compartments (1a-1i; 2a-2i) of either chamber (1, 2) are supplied with the same process gas or only in each case a selection of compartments (1a-1i; 2a-2i) that are not located one above the other are fed with the assigned process gas.

16. A chemical vapor deposition (CVD) reactor, comprising a gas inlet element having at least two chambers disposed one above the other, gas outlet openings (3, 4) starting in each case from a lower wall of the chambers, the gas outlet openings opening out into a process chamber for supply, into the process chamber, of in each case a process gas brought into the chambers (1, 2) by means of a feed line, a bottom of the process chamber being formed by a substrate holder that can be driven in rotation, characterized in that each of the at least two chambers is divided in each case into a plurality of compartments arranged in a distributed manner in a circumferential direction for supply to the process chamber either of a purge gas or a process gas via associated supply lines; and a gas mixing arrangement for selective supply either of all compartments of either chamber with the same process gas or only in each case a selection of the compartments that are not located one above the other with the process gas assigned to a respective chamber, wherein the substrate holder, which is disposed underneath the gas inlet element is rotatable about a central axis.
